(19) United States
(12) Patent Application Publication
(10) Pub. No.: US 2026/0231820 A1
(43) Pub. Date: Aug. 6, 2026

(54) SEMICONDUCTOR PACKAGE HAVING DUAL TRANSISTORS AND METHOD OF MAKING THE SAME

(71) Applicant: ALPHA AND OMEGA SEMICONDUCTOR INTERNATIONAL LP, TORONTO (CA)

(72) Inventors: Yan Xun Xue, Los Gatos, CA (US); Madhur Bobde, Sunnyvale, CA (US); Long-Ching Wang, Cupertino, CA (US); Zhiqiang Niu, Santa Clara, CA (US); Chunya Wen, Santa Clara, CA (US); Kuan-Hung Li, Zhubei City (TW)

(73) Assignee: ALPHA AND OMEGA SEMICONDUCTOR INTERNATIONAL LP, TORONTO (CA)

(21) Appl. No.: 19/045,283

(22) Filed: Feb. 4, 2025

(51) Int. Cl. H01L 25/07; H01L 21/56; H01L 23/00; H01L 23/31; H01L 23/495; H10D 80/20

(52) U.S. Cl. CPC H10W 90/00; H10D 80/251; H10W 70/417; H10W 70/481; H10W 74/114; H10W 72/0198; H10W 72/076; H10W 72/631; H10W 72/886; H10W 74/016; H10W 90/736; H10W 90/763

(57) ABSTRACT

A semiconductor package comprises a lead frame, a first field-effect transistor (FET), a second FET, a metal clip, and a molding encapsulation. Each of the first FET and the second FET is flipped. A method comprising the steps of providing a lead frame strip; mounting a first FET and a second FET; attaching a metal clip strip; forming a molding encapsulation; and applying a singulation process.

### FIELD OF THE INVENTION

This invention relates generally to a semiconductor package and a method of making the same. More particularly, the present invention relates to a package-level chip-scale power control module (PCM) having dual transistors.

### BACKGROUND OF THE INVENTION

Conventional chip-scale PCMs are fabricated from semiconductor wafers (wafer-level process). Each of the wafer-level chip-scale PCMs includes a thick metallization layer (for example, larger than 30 microns thick). A special carrier is required to support a wafer during the wafer thinning process thereby increasing a number of process steps and increasing a manufacturing cost.

A chip-scale PCM of the present disclosure is fabricated by building elements on a lead frame (package-level process). The thick metallization layer of the conventional wafer-level chip-scale PCM is replaced by a metal clip (for example, a copper clip) in the instant package-level chip-scale PCM so as to facilitate low source-to-source resistance (R_{SS}).

### SUMMARY OF THE INVENTION

The present invention discloses a semiconductor package comprising a lead frame, a first field-effect transistor (FET), a second FET, a metal clip, and a molding encapsulation. Each of the first FET and the second FET is flipped.

A method for fabricating a semiconductor package is also disclosed. The method comprises the steps of providing a lead frame strip; mounting a first FET and a second FET; attaching a metal clip strip; forming a molding encapsulation; and applying a singulation process.

### BRIEF DESCRIPTION OF THE DRAWINGS

FIG. 1A is a top perspective view, FIG. 1B is a bottom perspective view, and FIG. 1C is an exploded plot of a semiconductor package in examples of the present disclosure.

FIG. 2 is a top perspective view of another semiconductor package in examples of the present disclosure.

FIG. 3 is a flowchart of a process to fabricate a semiconductor package in examples of the present disclosure.

FIG. 4AA, 4BA, 4CA, 4DA, and 4EA are front views and FIG. 4AB, 4BB, 4CB, 4DB, 4EB, and 4F are top perspective views showing the steps of the process to fabricate the semiconductor package in examples of the present disclosure.

### DETAILED DESCRIPTION OF THE INVENTION

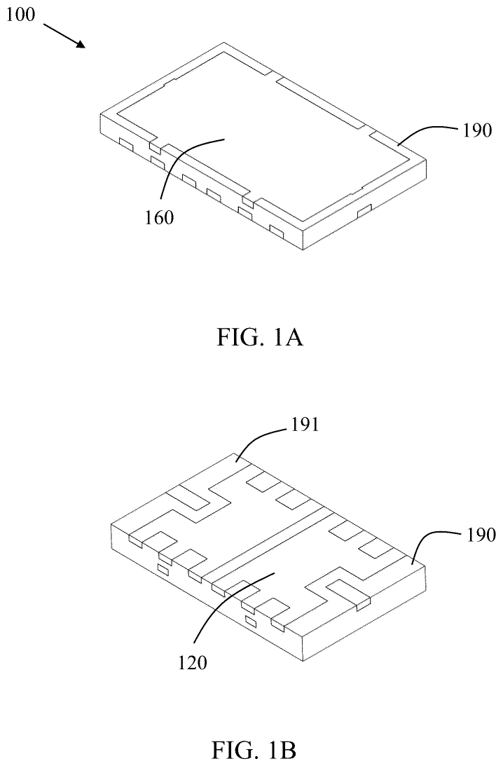

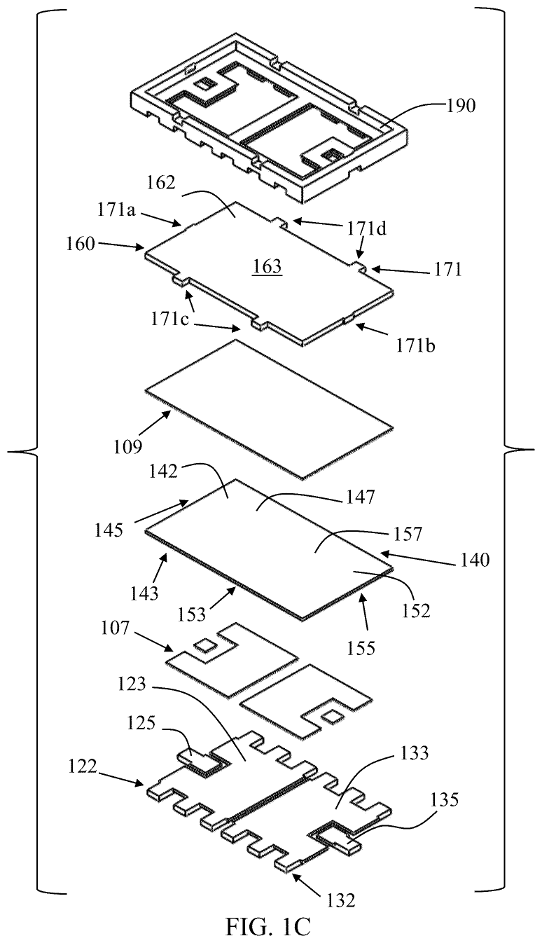

FIG. 1A is a top perspective view, FIG. 1B is a bottom perspective view, and FIG. 1C is an exploded plot of a semiconductor package 100 in examples of the present disclosure. In one example, the semiconductor package 100 is a double-diffusion metal-oxide-silicon field-effect transistor (DMOSFET) or a power control module (PCM). The semiconductor package 100 comprises a lead frame 120, a first FET 142, a second FET 152, a metal clip 160, and a molding encapsulation 190. The lead frame 120 comprises a first die paddle 122, and a second die paddle 132 separated from the first die paddle 122. The first die paddle 122 comprises a source paddle 123 and a gate lead 125 separated from the source paddle 123. The second die paddle 132 comprises a source paddle 133 and a gate lead 135 separated from the source paddle 133. In examples of the present disclosure, the first die paddle 122 and the second die paddle 132 are disposed side by side forming mirror image of each other. The gate lead 125 of the first die paddle 122 is disposed at a central location of a first side of the lead frame opposite the second die paddle 132 and extends beyond a notch of the source paddle 123 at the first side away from the second die paddle 132. The gate lead 135 of the second die paddle 132 is disposed at a central location of a second side of the lead frame opposite the first die paddle 122 and extends beyond a notch of the source paddle 133 at the second side away from the first die paddle 122. A plurality of first source leads connected to the source paddle 123 of the first die paddle 122 disposed on the third side of the lead frame 120 and the fourth side of the lead frame 120 opposite to the third side of the lead frame 120. A plurality of second source leads connected to the source paddle 133 of the second die paddle 132 disposed on the third side of the lead frame 120 and the fourth side of the lead frame 120 opposite to the third side of the lead frame 120.

In examples of the present disclosure, the semiconductor package 100 further comprises a first conductive adhesive layer 107 and a second conductive adhesive layer 109. The first conductive adhesive layer 107 is disposed between the first die paddle 122 and the first FET 142, and between the second die paddle 132 and the second FET 152. The second conductive adhesive layer 109 is disposed between the first FET 142 and metal clip 160, and between the second FET 152 and metal clip 160. In examples of the present disclosure, the first conductive adhesive layer 107 and the second conductive adhesive layer 109 are solder layers.

In examples of the present disclosure, the first FET 142 and the second FET 152 are arranged side-by-side. In examples of the present disclosure, the first FET 142 and the second FET 152 are included in a same die 140. In one example, the die 140 is of a rectangular prism shape. In examples of the present disclosure, the first FET 142, and the second FET 152 are single piece construction (fabricated at the same time). In examples of the present disclosure, the first FET 142, and the second FET 152 are formed from a same semiconductor substrate.

The first FET 142 is flipped and attached to the first die paddle 122. The first FET 142 comprises a source electrode 143 and a gate electrode 145 on a front surface of the first FET 142, and a drain electrode 147 on a back surface of the first FET 142. The second FET 152 is flipped and attached to the second die paddle 132. The second FET 152 comprises a source electrode 153 and a gate electrode 155 on a front surface of the second FET 152, and a drain electrode 157 on a back surface of the second FET 152.

The source electrode 143 of the first FET 142 is attached to the source paddle 123 of the first die paddle 122 of the lead frame 120 by the first conductive adhesive layer 107. The gate electrode 145 of the first FET 142 is attached to the gate lead 125 of the first die paddle 122 of the lead frame 120 by the first conductive adhesive layer 107. The source electrode 153 of the second FET 152 is attached to the source paddle 133 of the second die paddle 132 of the lead frame 120 by the first conductive adhesive layer 107. The gate electrode 155 of the second FET 152 is attached to the gate lead 135 of the second die paddle 132 of the lead frame 120 by the first conductive adhesive layer 107.

The metal clip 160 connects the drain electrode 147 of the first FET 142 to the drain electrode 157 of the second FET 152 through the second conductive adhesive layer 109. In one example, the metal clip 160 is made of copper. In examples of the present disclosure, the metal clip 160 comprises a body 162 and a plurality of tie bars 171 directly connected to the body 162. In one example, the body 162 is of a rectangular prism shape. In one example, a thickness of an entirety of the metal clip 160 is the same as a thickness of each of the tie bar of the plurality of tie bars 171. In examples of the present disclosure, the plurality of tie bars 171 include a first tie bar 171a connected to a first edge of the body 162, a second tie bar 171b connected to a second edge of the body 162 opposite the first edge, one or more additional tie bars 171c connected to a third edge of the body 162 perpendicular to the first and second edges of the body 162 and one or more yet additional tie bars 171d connected to a fourth edge of the body 162 opposite the third edge. In one example, the first tie bar 171a is vertically aligned to the gate lead 225 of the first die paddle 122. In one example, the second tie bar 171b is vertically aligned to the gate lead 235 of the second die paddle 132.

The molding encapsulation 190 encloses the first FET 142, the second FET 152, at least a majority portion of the metal clip 160, and a majority portion of the lead frame 120. A majority portion refers to larger than 50%. In examples of the present disclosure, a top surface 163 of the body 162 of the metal clip 160 is exposed from the molding encapsulation 190 so as to facilitate heat dissipation and reduction of thickness of the semiconductor package 100. In one example, the first tie bar 171a has an end surface covered by a first side surface of the molding encapsulation 190. In one example, the second tie bar 171b has an end surface covered by a second side surface of the molding encapsulation opposite the first side surface. In one example, end surfaces of the one or more additional tie bars 171c are exposed from a third side surface of the molding encapsulation 190 and are away from the bottom surface 191 of the molding encapsulation 190. In one example, end surfaces of the one or more yet additional tie bars 171d are exposed from a fourth side surface of the molding encapsulation 190 and are away from the bottom surface 191 of the molding encapsulation 190.

In examples of the present disclosure, a bottom surface of the first die paddle 122, and a bottom surface of the second die paddle 132 are exposed from a bottom surface 191 of the molding encapsulation 190. In examples of the present disclosure, an end surface of the gate lead 225 of the first die paddle 122 is exposed from the first side surface of the molding encapsulation 190 and is adjacent to the bottom surface 191 of the molding encapsulation 190. In examples of the present disclosure, an end surface of the gate lead 135 of the second die paddle 132 is exposed from the second side surface of the molding encapsulation 190 and is adjacent to the bottom surface 191 of the molding encapsulation 190. In examples of the present disclosure, end surfaces of the plurality of first source leads connected to the source paddle 123 of the first die paddle 122 are exposed from the third and fourth side surfaces of the molding encapsulation 190 and are adjacent to the bottom surface 191 of the molding encapsulation 190. In examples of the present disclosure, end surfaces of the plurality of second source leads connected to the source paddle 133 of the second die paddle 132 are exposed from the third and fourth side surfaces of the molding encapsulation 190 and are adjacent to the bottom surface 191 of the molding encapsulation 190.

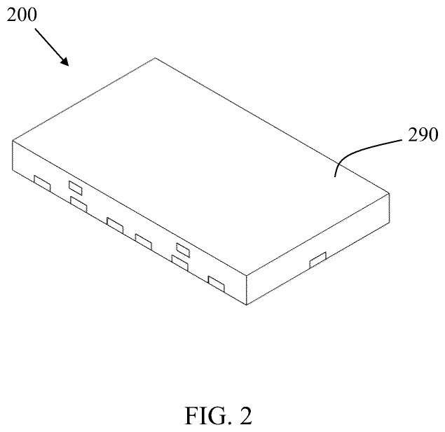

FIG. 2 is a top perspective view of a semiconductor package 200 in examples of the present disclosure. The semiconductor package 200 is similar to the semiconductor package 100 except that a top surface of a metal clip of the semiconductor package 200 is not exposed from a molding encapsulation 290 of the semiconductor package 200.

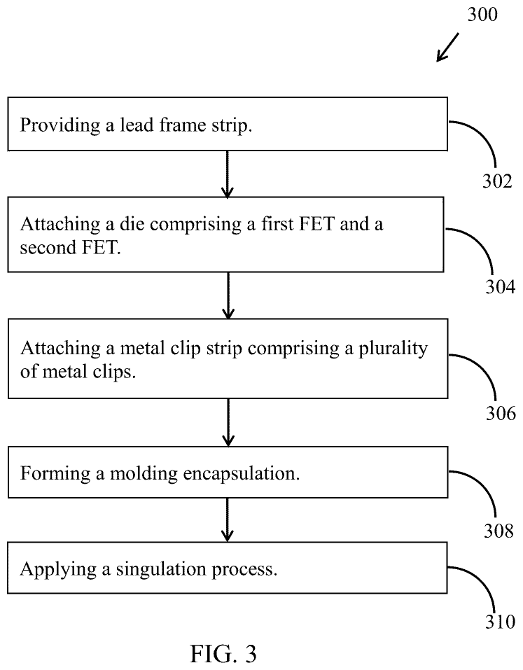

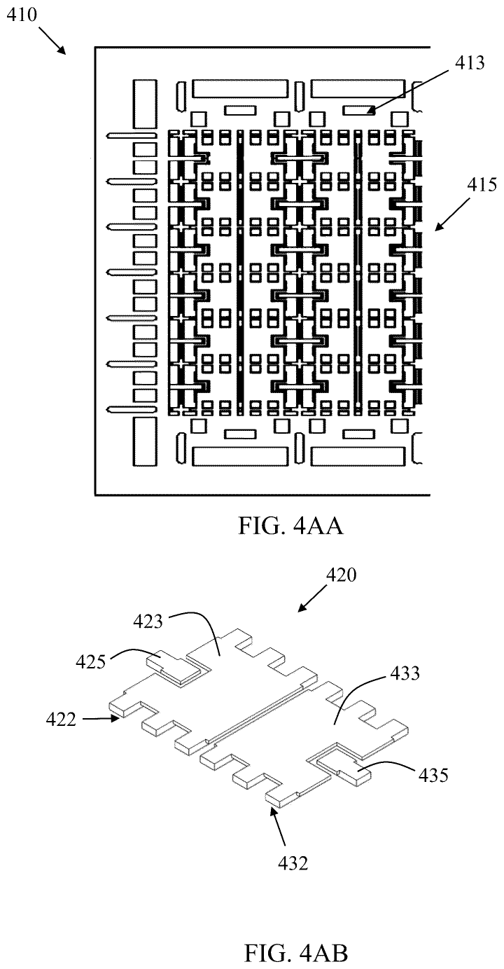

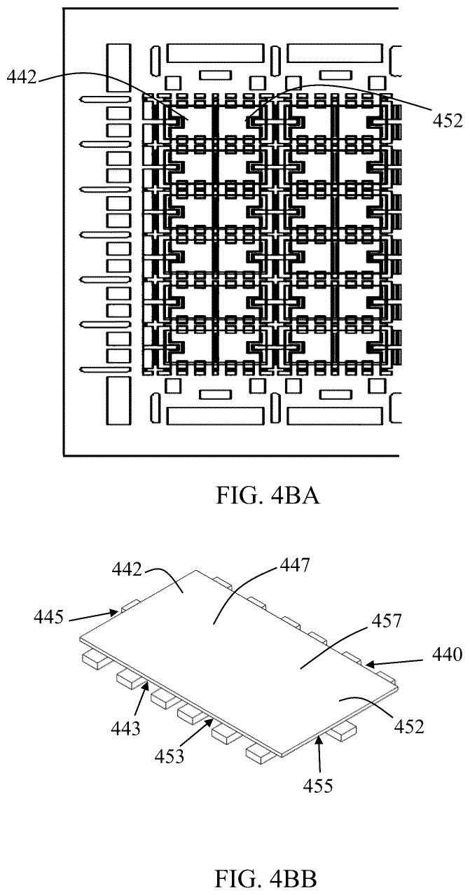

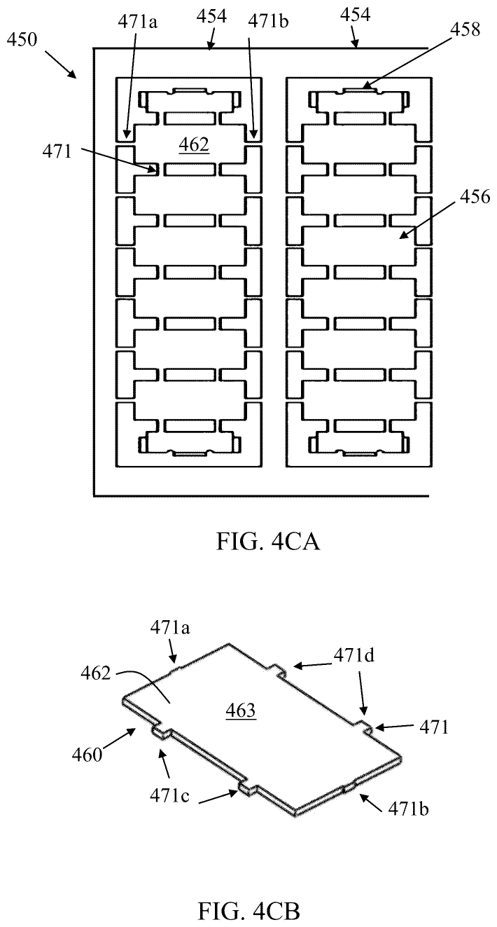

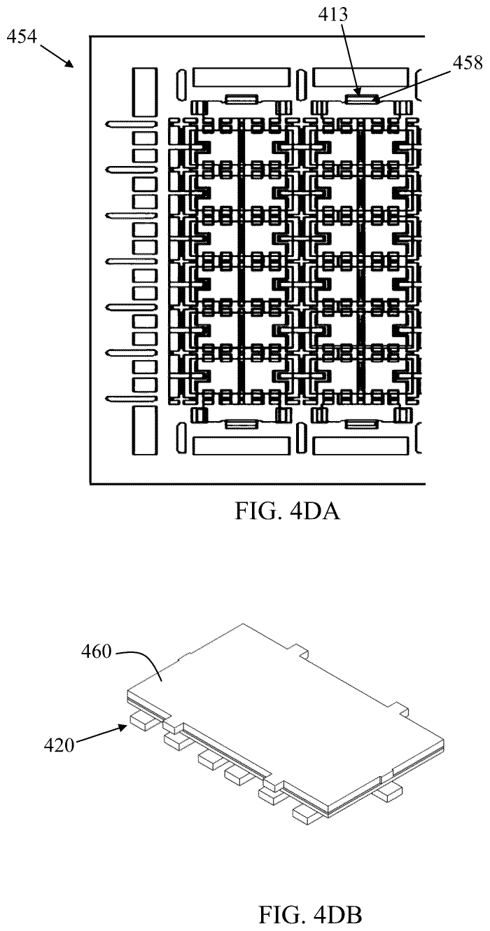

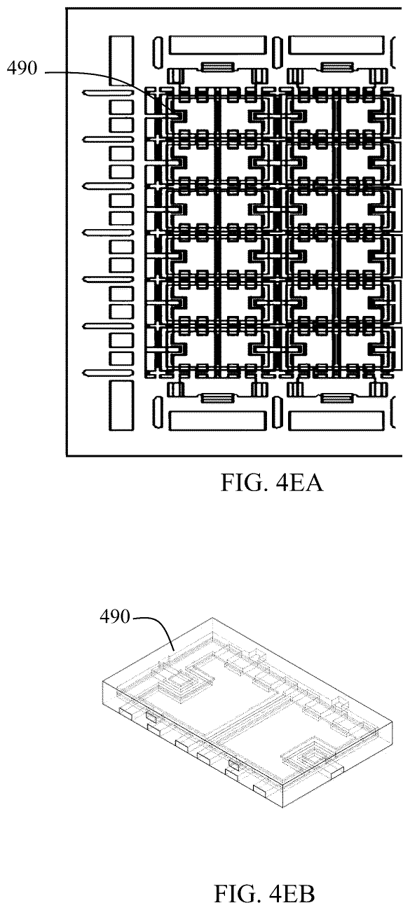

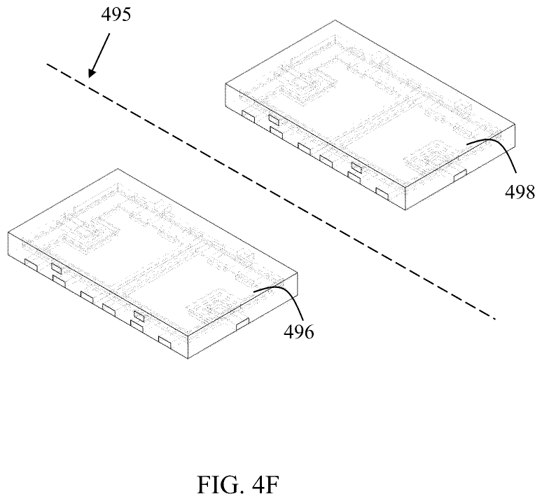

FIG. 3 is a flowchart of a process 300 to fabricate a semiconductor package in examples of the present disclosure. The process 300 may start from block 302. FIG. 4AA, 4BA, 4CA, 4DA, and 4EA show the process to fabricate a plurality of semiconductor packages. For simplicity, only the process to fabricate a single package is shown in FIG. 4AB, 4BB, 4CB, 4DB, and 4EB. For simplicity, only the process to fabricate two semiconductor packages is shown in FIG. 4F. FIG. 4AA, 4BA, 4CA, 4DA, and 4EA are front views and FIG. 4AB, 4BB, 4CB, 4DB, 4EB, and 4F are top perspective views.

In block 302, referring now to FIG. 4AA and 4AB, a lead frame strip 410 is provided. Though two columns are shown in FIG. 4AA, a number of columns may vary. Though six lead frames are shown in each column of FIG. 4AA, a number of lead frames in each column may vary. The lead frame strip 410 comprises a plurality of lead frames 415. A lead frame 420 of the plurality of lead frames 415 comprises a first die paddle 422, and a second die paddle 432 separated from the first die paddle 422. The first die paddle 422 comprises a source paddle 423 and a gate lead 425 separated from the source paddle 423. The second die paddle 432 comprises a source paddle 433 and a gate lead 435 separated from the source paddle 433. In examples of the present disclosure, the first die paddle 422 and the second die paddle 432 are disposed side by side forming mirror image of each other. The gate lead 425 of the first die paddle 422 is disposed at a central location of a first side of the lead frame opposite the second die paddle 432 and extends beyond a notch of the source paddle 423 at the first side away from the second die paddle 432. The gate lead 435 of the second die paddle 432 is disposed at a central location of a second side of the lead frame opposite the first die paddle 422 and extends beyond a notch of the source paddle 433 at the second side away from the first die paddle 422. A plurality of first source leads connected to the source paddle 423 of the first die paddle 422 disposed on the third side of the lead frame 420 and the fourth side of the lead frame 420 opposite to the third side of the lead frame 420. A plurality of second source leads connected to the source paddle 433 of the second die paddle 432 disposed on the third side of the lead frame 420 and the fourth side of the lead frame 420 opposite to the third side of the lead frame 420.

In examples of the present disclosure, the lead frame strip 410 comprises a plurality of locking holes 413 disposed at both ends of each column of lead frames. The plurality of locking holes 413 are of rectangular shapes. Block 302 may be followed by block 304.

In block 304, referring now to FIG. 4BA and 4BB, a first FET 442 and a second FET 452 are mounted. In one example, the first FET 442 and the second FET 452 are attached to the lead frame 420 by a solder layer (for example, the first solder layer 107 of FIG. 1C). In examples of the present disclosure, the first FET 442 and the second FET 452 are arranged side-by-side. In examples of the present disclosure, the first FET 442 and the second FET 452 are formed on a same die 440. In one example, the die 440 is of a rectangular prism shape. In examples of the present disclosure, the first FET 442, and the second FET 452 are single piece construction (fabricated at the same time). In examples of the present disclosure, the first FET 442, and the second FET 452 are formed from a same semiconductor substrate.

The first FET 442 is flipped and attached to the first die paddle 422. The first FET 442 comprises a source electrode 443 and a gate electrode 445 on a front surface of the first FET 442, and a drain electrode 447 on a back surface of the first FET 442. The second FET 452 is flipped and attached to the second die paddle 432. The second FET 452 comprises a source electrode 453 and a gate electrode 455 on a front surface of the second FET 452, and a drain electrode 457 on a back surface of the second FET 452.

The source electrode 443 of the first FET 442 is attached to the source paddle 423 of the first die paddle 422 of the lead frame 420. The gate electrode 445 of the first FET 442 is attached to the gate lead 425 of the first die paddle 422 of the lead frame 420. The source electrode 453 of the second FET 452 is attached to the source paddle 433 of the second die paddle 432 of the lead frame 420. The gate electrode 455 of the second FET 452 is attached to the gate lead 435 of the second die paddle 432 of the lead frame 420. Block 304 may be followed by block 306.

In block 306, referring now to 4CA, 4CB, 4DA, and 4DB, a metal clip strip 450 is provided. FIG. 4CA shows a metal clip strip 450 comprises two or more metal clip columns 454. The metal clip strip 450 comprises a plurality of metal clips 456. Each metal clip column comprises a subset of the plurality of metal clips 456. In one example, FIG. 4DA shows the two or more metal clip columns 454 being mounted on the first FET 442 and the second FET 452 by a solder layer (for example, the second solder layer 109 of FIG. 1C). In examples of the present disclosure, each of the metal clip column of the two or more metal clip columns 454 comprises a plurality of metal clips 456 (including a metal clip 460 of FIG. 4CB) and a plurality of locking inserts 458 at both ends of each metal clip column of the two or more metal clip columns 454. Each metal clip of the plurality of metal clips 456 comprises a body 462 and a plurality of tie bars 471 connecting adjacent metal clips and a frame of the metal clip column of the two or more metal clip columns 454. The plurality of tie bars 471 include a first tie bar 471a connecting the body 462 to the frame of the metal clip column of the two or more metal clip columns 454 at a first side and a second tie bar 471b connecting the body 462 to the frame of the metal clip column of the two or more metal clip columns 454 at a second side of the body 462 opposite the first side. In process each metal clip column of the two or more metal clip columns 454 of the metal clip strip 450 is separated from the metal clip strip 450 by cutting off the tie bars 471a and 471b of each metal clip of the subset of the plurality of metal clips 456 and being placed on top of the first FET 442 and the second FET shown in FIG. 4DA. The number of the metal clips in each metal clip column of the two or more metal clip columns 454 matches the number of lead frames in each lead frame column. The pattern of each of the plurality of locking inserts 458 of the metal clip strip 450 matches the pattern of each of the locking holes 413. In one example, a locking insert of a rectangular pattern matches a locking hole of a rectangular pattern. The plurality of locking inserts 458 of the metal clip strip 45 are engaged to the plurality of locking holes 413 of the lead frame strip 410.

The metal clip 460 connects the drain electrode 447 of the first FET 442 to the drain electrode 457 of the second FET 452. In one example, the metal clip 460 is made of copper. In examples of the present disclosure, the metal clip 460 comprises a body 462 and a plurality of tie bars 471 directly connected to the body 462. In one example, the body 462 is of a rectangular prism shape. In one example, a thickness of an entirety of the metal clip 460 is the same as a thickness of each of the tie bar of the plurality of tie bars 471. In one example, a remaining portion of the first tie bar 471a is vertically aligned to the gate lead 425 of the first die paddle 422. In one example, a remaining portion of the second tie bar 471b is vertically aligned to the gate lead 435 of the second die paddle 432. Block 306 may be followed by block 308.

In block 308, referring now to FIG. 4EA and 4EB, a molding encapsulation 490 is formed. The molding encapsulation 490 encloses the first FET 442, the second FET 452, at least a majority portion of the metal clip 460, and a majority portion of the lead frame 420. A majority portion refers to larger than 50%. In one example, a top surface 463 (FIG. 4CB) of the body 462 of the metal clip 460 is exposed from the molding encapsulation 490 so as to facilitate heat dissipation and reduction of thickness of the semiconductor package 496 (FIG. 4F). In another example, a top surface of a metal clip of the semiconductor package 200 (FIG. 2) is not exposed from a molding encapsulation 490 of the semiconductor package 200 (FIG. 2).

In examples of the present disclosure, a bottom surface of the first die paddle 422, and a bottom surface of the second die paddle 432 are exposed from a bottom surface 191 (FIG. 1B) of the molding encapsulation 490. Block 308 may be followed by block 310.

In block 310, referring now to FIG. 4F, a singulation process along the line 495 is applied. The semiconductor package 496 is separated from an adjacent semiconductor package 498. Although only two semiconductor packages are shown in FIG. 4F, the number of semiconductor packages to be separated in a same singulation process may vary. In one example, the remaining portion of the first tie bar 471a has an end surface covered by a first side surface of the molding encapsulation 490. In one example, the remaining portion of the second tie bar 471b has an end surface covered by a second side surface of the molding encapsulation opposite the first side surface. In one example, end surfaces of the one or more additional tie bars 471c are exposed from a third side surface of the molding encapsulation 490 and are away from the bottom surface of the molding encapsulation 490. In one example, end surfaces of the one or more additional tie bars 471d are exposed from a fourth side surface of the molding encapsulation 490 and are away from the bottom surface of the molding encapsulation 490.

In examples of the present disclosure, an end surface of the gate lead 425 of the first die paddle 422 is exposed from the first side surface of the molding encapsulation 490 and is adjacent to the bottom surface of the molding encapsulation 490. In examples of the present disclosure, an end surface of the gate lead 435 of the second die paddle 432 is exposed from the second side surface of the molding encapsulation 490 and is adjacent to the bottom surface of the molding encapsulation 490. In examples of the present disclosure, end surfaces of the plurality of first source leads connected to the source paddle 423 of the first die paddle 422 are exposed from the third and fourth side surfaces of the molding encapsulation 490 and are adjacent to the bottom surface of the molding encapsulation 490. In examples of the present disclosure, end surfaces of the plurality of second source leads connected to the source paddle 433 of the second die paddle 432 are exposed from the third and fourth side surfaces of the molding encapsulation 490 and are adjacent to the bottom surface of the molding encapsulation 490. In one example, the semiconductor package 496 is a double-diffusion metal-oxide-silicon field-effect transistor (DMOSFET) or a power control module (PCM).

Those of ordinary skill in the art may recognize that modifications of the embodiments disclosed herein are possible. For example, a number of tie bars may vary. Other modifications may occur to those of ordinary skill in this art, and all such modifications are deemed to fall within the purview of the present invention, as defined by the claims.

1. A semiconductor package comprising:
a lead frame comprising
a first die paddle comprising:
a source paddle; and
a gate lead; and
a second die paddle comprising:
a source paddle; and
a gate lead;
a first field-effect transistor (FET) being flipped and attached to the first die paddle, the first FET comprising:
a source electrode and a gate electrode on a front surface of the first FET; and
a drain electrode on a back surface of the first FET;
a second FET being flipped and attached to the second die paddle, the second FET comprising:
a source electrode and a gate electrode on a front surface of the second FET; and
a drain electrode on a back surface of the second FET;
a metal clip connecting the drain electrode of the first FET to the drain electrode of the second FET; and
a molding encapsulation enclosing the first FET, the second FET, at least a majority portion of the metal clip, and a majority portion of the lead frame.

2. The semiconductor package of claim 1, wherein the first FET and the second FET are formed on a same die.

3. The semiconductor package of claim 2, wherein the gate lead of the first die paddle is disposed at a central location of a first side of the lead frame opposite the second die paddle and extends beyond a notch of the source paddle of the first die paddle; and wherein the gate lead of the second die paddle is disposed at a central location of a second side of the lead frame opposite the first side and extends beyond a notch of the source paddle of the second die paddle.

4. The semiconductor package of claim 1, wherein the source electrode of the first FET is attached to the source paddle of the first die paddle of the lead frame;
wherein the gate electrode of the first FET is attached to the gate lead of the first die paddle of the lead frame;
wherein the source electrode of the second FET is attached to the source paddle of the second die paddle of the lead frame; and
wherein the gate electrode of the second FET is attached to the gate lead of the second die paddle of the lead frame.

5. The semiconductor package of claim 1, wherein the metal clip comprises:
a body of a rectangular prism shape; and
a plurality of tie bars directly connected to the body.

6. The semiconductor package of claim 5, wherein a top surface of the body of the metal clip is exposed from the molding encapsulation.

7. The semiconductor package of claim 5, wherein a top surface of the body of the metal clip is not exposed from the molding encapsulation.

8. The semiconductor package of claim 5, wherein the plurality of tie bars comprise a first tie bar vertically aligned to the gate lead of the first die paddle and a second tie bar vertically aligned to the gate lead of the second die paddle.

9. The semiconductor package of claim 8, wherein an end surface of the first tie bar is covered by a first side surface of the molding encapsulation and an end surface of the second tie bar is covered by a second side surface of the molding encapsulation opposite the first side surface of the molding encapsulation.

10. The semiconductor package of claim 1 further comprising a first conductive adhesive layer disposed between the first die paddle and the first FET, and between the second die paddle and the second FET; and a second conductive adhesive layer disposed between the first FET and the metal clip, and between the second FET and the metal clip.

11. A method for fabricating a semiconductor package, the method comprising the steps of:
providing a lead frame strip comprising a plurality of lead frames, each lead frame of the plurality of lead frames comprising:
a first die paddle comprising:
a source paddle; and
a gate lead; and
a second die paddle comprising:
a source paddle; and
a gate lead;
attaching a first field-effect transistor (FET) and a second FET to said each lead frame,
the first FET being flipped and attached to the first die paddle, the first FET comprising:
a source electrode and a gate electrode on a front surface of the first FET; and
a drain electrode on a back surface of the first FET;
the second FET being flipped and attached to the second die paddle, the second FET comprising:
a source electrode and a gate electrode on a front surface of the second FET; and
a drain electrode on a back surface of the second FET;
providing a metal clip strip comprising a plurality of metal clips, a respective metal clip of the plurality of metal clips connecting the drain electrode of the first FET to the drain electrode of the second FET;
forming a molding encapsulation enclosing the first FET, the second FET, at least a majority portion of the respective metal clip, and a majority portion of said each lead frame; and
applying a singulation process separating the semiconductor package from adjacent semiconductor packages.

12. The method of claim 11, wherein the first FET and the second FET are formed on a same die.

13. The method of claim 11, wherein the lead frame strip comprises two or more lead frame columns;
wherein each lead frame column of the two or more lead frame columns comprises a subset of the plurality of lead frames;
wherein a plurality of locking holes are disposed at a first end and a second end of said each lead frame column; and
wherein the first end of said each lead frame column is opposite to the second end of said each lead frame column.

14. The method of claim 13, wherein the metal clip strip comprises two or more metal clip columns;
wherein each metal clip column of the two or more metal clip columns comprises:
a subset of the plurality of metal clips; and
a plurality of locking inserts at a first end and a second end of said each metal clip column; and
wherein the first end of said each metal clip column is opposite to the second end of said each metal clip column.

15. The method of claim 14, wherein the respective metal clip comprises:
a body of a rectangular prism shape; and
a plurality of tie bars directly connected to the body.

16. The method of claim 15, wherein a top surface of the body of the respective metal clip is exposed from the molding encapsulation.

17. The method of claim 15, wherein a top surface of the body of the respective metal clip is not exposed from the molding encapsulation.

18. The method of claim 15, wherein a number of metal clips in each metal clip column matches the number of lead frames in each lead frame column; and wherein a pattern of each locking insert of the plurality of locking inserts matches a pattern of each locking hole of the plurality of locking holes.

19. The method of claim 18 further comprising a step of separating a selected metal clip column from remaining metal clip columns of the metal clip strip; and a step of placing the selected metal clip column on top of the first FET and the second FET.

20. The method of claim 19, the step of providing the metal clip strip comprising the sub-steps of:
engaging the plurality of locking inserts of the metal clip column to the plurality of locking holes of the lead frame column.
